(19) United States
(12) Patent Application Publication
(10) Pub. No.: US 2024/0142863 A1
(43) Pub. Date: May 2, 2024

(54) HEAT DISSIPATION DEVICE FOR VEHICLE PROJECTORS

(71) Applicant: HYUNDAI MOBIS CO., LTD., Seoul (KR)

(72) Inventor: Sung Joon AHN, Seoul (KR)

(73) Assignee: HYUNDAI MOBIS CO., LTD., Seoul (KR)

(21) Appl. No.: 18/466,130

(22) Filed: Sep. 13, 2023

(30) Foreign Application Priority Data
Nov. 2, 2022 (KR) 10-2022-0144348

(51) Int. Cl. G03B 21/16; B60H 1/00; H05K 7/20

(52) U.S. Cl. CPC G03B 21/16; B60H 1/00271; B60H 1/00328; H05K 7/20154; H05K 7/20409

(57) ABSTRACT

A heat dissipation device for vehicle projectors including a projector disposed on a headlining of a vehicle, a projector heat sink provided in the projector, the projector heat sink being configured to conduct heat generated by the projector to an outside of the projector, a thermal conductor disposed on top of the projector heat sink, and an external heat sink disposed on top of the thermal conductor, the external heat sink being configured to dissipate heat conducted by the thermal conductor to an outside of the vehicle, the thermal conductor being configured to facilitate heat exchange between the projector heat sink and the external heat sink by transferring the heat from the projector heat sink to the external heat sink.

This application claims the benefit under 35 U.S.C. § 119(a) of Korean Patent Application No. 10-2022-0144348, filed on November 02, 2022 the disclosure of which is hereby incorporated by reference for all purposes.

### BACKGROUND

### 1. Field of the Disclosure

The present embodiments are applicable to vehicles in all fields and, and more particularly, to various systems that allow autonomous vehicles to avoid collisions with front vehicles.

### 2. Discussion of the Related Art

In general, vehicles are equipped with vehicle air conditioning systems that circulate cooled or heated air into the interior thereof for cooling and heating to provide a comfortable interior environment.

In conventional vehicle air conditioning systems, a temperature control device activates an interior air conditioner (A/C) switch. When air is set to be circulated from the outside or within the interior, a blower operates to force indoor or outdoor air into an evaporator of a cooling unit or a heater core of a heater unit installed in an air duct. The air circulated to the evaporator or heater core is then discharged into the interior of the vehicle in a cooled or heated state, enabling cooling or heating within the vehicle interior.

Recently, technologies have been developed to project projector images onto windshield glass to use the windshield glass as a display in consideration of autonomous driving environments and various vehicle types. When using the projector in an open space, it is relatively easy to dissipate the heat generated by the projector to the surrounding environment. However, when configuring the projector in a closed space such as a vehicle, there may be difficulties in dissipating the heat generated by the projector. Additionally, when it is difficult to dissipate the heat generated by the projector, it may result in the following issues: abnormal image quality, image blackout, malfunctions, and the like.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a heat dissipation device including a projector disposed on a headlining of a vehicle, a projector heat sink provided in the projector, the projector heat sink being configured to conduct heat generated by the projector to an outside of the projector, a thermal conductor disposed on top of the projector heat sink, and an external heat sink disposed on top of the thermal conductor, the external heat sink being configured to dissipate heat conducted by the thermal conductor to an outside of the vehicle, the thermal conductor being configured to facilitate heat exchange between the projector heat sink and the external heat sink by transferring the heat from the projector heat sink to the external heat sink.

The thermal conductor may include a first side configured to absorb heat from the projector heat sink and a second side configured to release the absorbed heat to the external heat sink.

The external heat sink may include a main body in contact with the thermal conductor and protrusions disposed on the main body, the protrusions being exposed to the outside of the vehicle by passing through a roof panel of the vehicle and arranged in a direction of travel of the vehicle for heat dissipation by a flow of outside air.

The heat dissipation device may include a first plurality of thermal pads disposed between the projector heat sink and a first side of the thermal conductor and a second plurality of thermal pads disposed between a second side of the thermal conductor and the external heat sink.

In a general aspect, here is provided a heat dissipation device including a projector disposed on a headlining of a vehicle, a projector heat sink provided in the projector, the projector heat sink being configured to release heat generated by the projector to an outside of the projector, and a heat dissipation fan disposed above the projector heat sink, the heat dissipation fan being configured to release heat from a space between the headlining and a roof panel to an outside of the vehicle.

The roof panel may include an opening defined therein configured to allow the heat released by the heat dissipation fan to be discharged to the outside of the vehicle, and the roof panel may be sloped to guide the heat to the outside of the vehicle.

The heat dissipation device may include a cover panel coupled to an open upper surface of the roof panel, the cover panel being configured to prevent the heat dissipation fan from being exposed to the outside of the vehicle.

The heat dissipation device may include a barrier formed between the heat dissipation fan and the roof panel, the barrier being configured to prevent moisture that enters through a gap between the roof panel and the cover panel from entering the heat dissipation fan.

The roof panel may include a drain hole defined within a slope of the roof panel, and the heat dissipation device may include a drain hose connected to the drain hole and configured to discharge the entering moisture to an outside of the heat dissipation device.

In a general aspect, here is provided a device including a first heat sink associated with an electronic device exposed in a passenger area of a vehicle, a thermal conductor provided on the first heat sink, and a second heat sink provided on a first side of the thermal conductor, the first heat sink being provided on a second side of the thermal conductor opposite to the first side of the thermal conductor, the second heat sink being configured to dissipate heat from the electronic device to an outside of the vehicle.

The electronic device may be provided in a headlining of a vehicle.

The electronic device may be a projector provided in a headlining of a vehicle.

The thermal conductor may be configured to transfer heat from the first heat sink to the second heat sink.

The second heat sink may include a main body disposed on the second side of the thermal conductor and protrusions extending from the main body.

The vehicle may include a roof having an opening defined therein to receive the protrusions, the protrusions being configured to extend to an outside from the roof.

The vehicle may include a roof having an opening defined therein to receive the second heat sink, the second heat sink being incorporated into the roof and the protrusions being configured to extend to an outside from the roof.

The vehicle may include a roof portion configured to house the electronic device, the second heat sink contacting a roof panel of the roof portion, the second heat sink being configured to dispel the heat to an outside of the vehicle through the roof portion.

### BRIEF DESCRIPTION OF THE DRAWINGS

FIG. 1 is an overall block diagram of an autonomous driving control system to which an autonomous driving apparatus according to an embodiment of the present disclosure is applicable;

FIG. 2 is a diagram illustrating an example in which the autonomous driving apparatus according to an embodiment of the present disclosure is applied to a vehicle;

FIGS. 3 to 6 are diagrams for explaining a heat dissipation device for vehicle projectors using a thermal conductor and an external heat sink according to an embodiment of the present disclosure;

FIGS. 7 to 9 are diagrams for explaining a heat dissipation device for vehicle projectors using a thermal conductor according to an embodiment of the present disclosure; and

FIGS. 10 and 11 are diagrams for explaining a heat dissipation device for vehicle projectors using a heat dissipation fan according to an embodiment of the present disclosure.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Advantages and features of the present disclosure and methods of achieving the advantages and features will be clear with reference to embodiments described in detail below together with the accompanying drawings. However, the present disclosure is not limited to the embodiments disclosed herein but will be implemented in various forms. The embodiments of the present disclosure are provided so that the present disclosure is completely disclosed, and a person with ordinary skill in the art can fully understand the scope of the present disclosure. The present disclosure will be defined only by the scope of the appended claims. Meanwhile, the terms used in the present specification are for explaining the embodiments, not for limiting the present disclosure.

Terms, such as first, second, A, B, (a), (b) or the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween.

In a description of the embodiment, in a case in which any one element is described as being formed on or under another element, such a description includes both a case in which the two elements are formed in direct contact with each other and a case in which the two elements are in indirect contact with each other with one or more other elements interposed between the two elements. In addition, when one element is described as being formed on or under another element, such a description may include a case in which the one element is formed at an upper side or a lower side with respect to another element.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

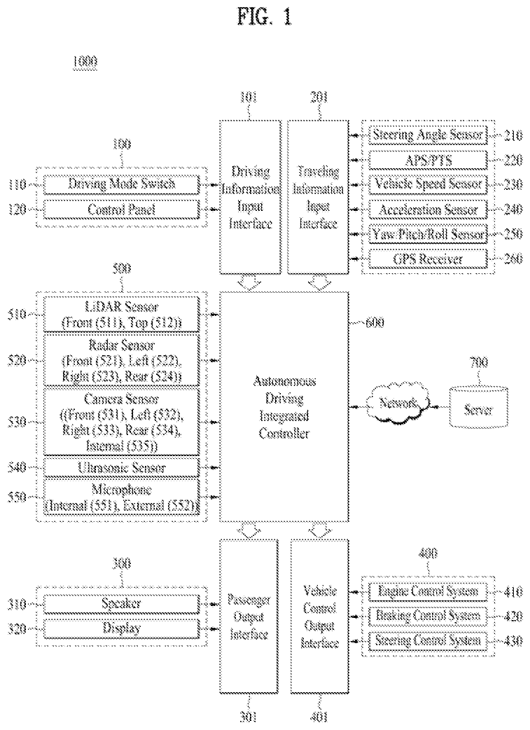

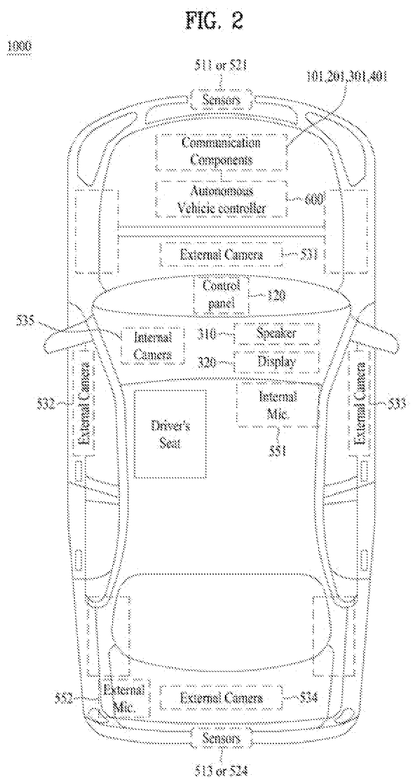

FIG. 1 is an overall block diagram of an autonomous driving control system to which an autonomous driving apparatus according to any one of embodiments of the present disclosure is applicable. FIG. 2 is a diagram illustrating an example in which an autonomous driving apparatus according to any one of embodiments of the present disclosure is applied to a vehicle.

First, a structure and function of an autonomous driving control system (e.g., an autonomous driving vehicle) to which an autonomous driving apparatus according to the present embodiments is applicable will be described with reference to FIGS. 1 and 2.

As illustrated in FIG. 1, an autonomous driving vehicle 1000 may be implemented based on an autonomous driving integrated controller 600 that transmits and receives data necessary for autonomous driving control of a vehicle through a driving information input interface 101, a traveling information input interface 201, an occupant output interface 301, and a vehicle control output interface 401. However, the autonomous driving integrated controller 600 may also be referred to herein as a controller, a processor, or, simply, a controller.

The autonomous driving integrated controller 600 may obtain, through the driving information input interface 101, driving information based on manipulation of an occupant for a user input unit 100 in an autonomous driving mode or manual driving mode of a vehicle. As illustrated in FIG. 1, the user input unit 100 may include a driving mode switch 110 and a control panel 120 (e.g., a navigation terminal mounted on the vehicle or a smartphone or tablet computer owned by the occupant). Accordingly, driving information may include driving mode information and navigation information of a vehicle.

For example, a driving mode (i.e., an autonomous driving mode/manual driving mode or a sports mode/eco mode/safety mode/normal mode) of the vehicle determined by manipulation of the occupant for the driving mode switch 110 may be transmitted to the autonomous driving integrated controller 600 through the driving information input interface 101 as the driving information.

Furthermore, navigation information, such as the destination of the occupant input through the control panel 120 and a path up to the destination (e.g., the shortest path or preference path, selected by the occupant, among candidate paths up to the destination), may be transmitted to the autonomous driving integrated controller 600 through the driving information input interface 101 as the driving information.

The control panel 120 may be implemented as a touchscreen panel that provides a user interface (UI) through which the occupant inputs or modifies information for autonomous driving control of the vehicle. In this case, the driving mode switch 110 may be implemented as touch buttons on the control panel 120.

In addition, the autonomous driving integrated controller 600 may obtain traveling information indicative of a driving state of the vehicle through the traveling information input interface 201. The traveling information may include a steering angle formed when the occupant manipulates a steering wheel, an accelerator pedal stroke or brake pedal stroke formed when the occupant depresses an accelerator pedal or brake pedal, and various types of information indicative of driving states and behaviors of the vehicle, such as a vehicle speed, acceleration, a yaw, a pitch, and a roll formed in the vehicle. The traveling information may be detected by a traveling information detection unit 200, including a steering angle sensor 210, an accelerator position sensor (APS)/pedal travel sensor (PTS) 220, a vehicle speed sensor 230, an acceleration sensor 240, and a yaw/pitch/roll sensor 250, as illustrated in FIG. 1.

Furthermore, the traveling information of the vehicle may include location information of the vehicle. The location information of the vehicle may be obtained through a global positioning system (GPS) receiver 260 applied to the vehicle. Such traveling information may be transmitted to the autonomous driving integrated controller 600 through the traveling information input interface 201 and may be used to control the driving of the vehicle in the autonomous driving mode or manual driving mode of the vehicle.

The autonomous driving integrated controller 600 may transmit driving state information provided to the occupant to an output unit 300 through the occupant output interface 301 in the autonomous driving mode or manual driving mode of the vehicle. That is, the autonomous driving integrated controller 600 transmits the driving state information of the vehicle to the output unit 300 so that the occupant may check the autonomous driving state or manual driving state of the vehicle based on the driving state information output through the output unit 300. The driving state information may include various types of information indicative of driving states of the vehicle, such as a current driving mode, transmission range, and speed of the vehicle.

If it is determined that it is necessary to warn a driver in the autonomous driving mode or manual driving mode of the vehicle along with the above driving state information, the autonomous driving integrated controller 600 transmits warning information to the output unit 300 through the occupant output interface 301 so that the output unit 300 may output a warning to the driver. In order to output such driving state information and warning information acoustically and visually, the output unit 300 may include a speaker 310 and a display 320 as illustrated in FIG. 1. In this case, the display 320 may be implemented as the same device as the control panel 120 or may be implemented as an independent device separated from the control panel 120.

Furthermore, the autonomous driving integrated controller 600 may transmit control information for driving control of the vehicle to a lower control system 400, applied to the vehicle, through the vehicle control output interface 401 in the autonomous driving mode or manual driving mode of the vehicle. As illustrated in FIG. 1, the lower control system 400 for driving control of the vehicle may include an engine control system 410, a braking control system 420, and a steering control system 430. The autonomous driving integrated controller 600 may transmit engine control information, braking control information, and steering control information, as the control information, to the respective lower control systems 410, 420, and 430 through the vehicle control output interface 401. Accordingly, the engine control system 410 may control the speed and acceleration of the vehicle by increasing or decreasing fuel supplied to an engine. The braking control system 420 may control the braking of the vehicle by controlling braking power of the vehicle. The steering control system 430 may control the steering of the vehicle through a steering device (e.g., motor driven power steering (MDPS) system) applied to the vehicle.

As described above, the autonomous driving integrated controller 600 according to the present embodiment may obtain the driving information based on manipulation of the driver and the traveling information indicative of the driving state of the vehicle through the driving information input interface 101 and the traveling information input interface 201, respectively, and transmit the driving state information and the warning information, generated based on an autonomous driving algorithm, to the output unit 300 through the occupant output interface 301. In addition, the autonomous driving integrated controller 600 may transmit the control information generated based on the autonomous driving algorithm to the lower control system 400 through the vehicle control output interface 401 so that driving control of the vehicle is performed.

In order to guarantee stable autonomous driving of the vehicle, it is necessary to continuously monitor the driving state of the vehicle by accurately measuring a driving environment of the vehicle and to control driving based on the measured driving environment. To this end, as illustrated in FIG. 1, the autonomous driving apparatus according to the present embodiment may include a sensor unit 500 for detecting a nearby object of the vehicle, such as a nearby vehicle, pedestrian, road, or fixed facility (e.g., a signal light, a signpost, a traffic sign, or a construction fence).

The sensor unit 500 may include one or more of a LiDAR sensor 510, a radar sensor 520, or a camera sensor 530, in order to detect a nearby object outside the vehicle, as illustrated in FIG. 1.

The LiDAR sensor 510 may transmit a laser signal to the periphery of the vehicle and detect a nearby object outside the vehicle by receiving a signal reflected and returning from a corresponding object. The LiDAR sensor 510 may detect a nearby object located within the ranges of a preset distance, a preset vertical field of view, and a preset horizontal field of view, which are predefined depending on specifications thereof. The LiDAR sensor 510 may include a front LiDAR sensor 511, a top LiDAR sensor 512, and a rear LiDAR sensor 513 installed at the front, top, and rear of the vehicle, respectively, but the installation location of each LiDAR sensor and the number of LiDAR sensors installed are not limited to a specific embodiment. A threshold for determining the validity of a laser signal reflected and returning from a corresponding object may be previously stored in a memory (not illustrated) of the autonomous driving integrated controller 600. The autonomous driving integrated controller 600 may determine a location (including a distance to a corresponding object), speed, and moving direction of the corresponding object using a method of measuring time taken for a laser signal, transmitted through the LiDAR sensor 510, to be reflected and returning from the corresponding object.

The radar sensor 520 may radiate electromagnetic waves around the vehicle and detect a nearby object outside the vehicle by receiving a signal reflected and returning from a corresponding object. The radar sensor 520 may detect a nearby object within the ranges of a preset distance, a preset vertical field of view, and a preset horizontal field of view, which are predefined depending on specifications thereof. The radar sensor 520 may include a front radar sensor 521, a left radar sensor 522, a right radar sensor 523, and a rear radar sensor 524 installed at the front, left, right, and rear of the vehicle, respectively, but the installation location of each radar sensor and the number of radar sensors installed are not limited to a specific embodiment. The autonomous driving integrated controller 600 may determine a location (including a distance to a corresponding object), speed, and moving direction of the corresponding object using a method of analyzing power of electromagnetic waves transmitted and received through the radar sensor 520.

The camera sensor 530 may detect a nearby object outside the vehicle by photographing the periphery of the vehicle and detect a nearby object within the ranges of a preset distance, a preset vertical field of view, and a preset horizontal field of view, which are predefined depending on specifications thereof.

The camera sensor 530 may include a front camera sensor 531, a left camera sensor 532, a right camera sensor 533, and a rear camera sensor 534 installed at the front, left, right, and rear of the vehicle, respectively, but the installation location of each camera sensor and the number of camera sensors installed are not limited to a specific embodiment. The autonomous driving integrated controller 600 may determine a location (including a distance to a corresponding object), speed, and moving direction of the corresponding object by applying predefined image processing to an image captured by the camera sensor 530.

In addition, an internal camera sensor 535 for capturing the inside of the vehicle may be mounted at a predetermined location (e.g., rear view mirror) within the vehicle. The autonomous driving integrated controller 600 may monitor a behavior and state of the occupant based on an image captured by the internal camera sensor 535 and output guidance or a warning to the occupant through the output unit 300.

As illustrated in FIG. 1, the sensor unit 500 may further include an ultrasonic sensor 540 in addition to the LiDAR sensor 510, the radar sensor 520, and the camera sensor 530 and further adopt various types of sensors for detecting a nearby object of the vehicle along with the sensors.

FIG. 2 illustrates an example in which, in order to aid in understanding the present embodiment, the front LiDAR sensor 511 or the front radar sensor 521 is installed at the front of the vehicle, the rear LiDAR sensor 513 or the rear radar sensor 524 is installed at the rear of the vehicle, and the front camera sensor 531, the left camera sensor 532, the right camera sensor 533, and the rear camera sensor 534 are installed at the front, left, right, and rear of the vehicle, respectively. However, as described above, the installation location of each sensor and the number of sensors installed are not limited to a specific embodiment.

Furthermore, in order to determine a state of the occupant within the vehicle, the sensor unit 500 may further include a bio sensor for detecting bio signals (e.g., heart rate, electrocardiogram, respiration, blood pressure, body temperature, electroencephalogram, photoplethysmography (or pulse wave), and blood sugar) of the occupant. The bio sensor may include a heart rate sensor, an electrocardiogram sensor, a respiration sensor, a blood pressure sensor, a body temperature sensor, an electroencephalogram sensor, a photoplethysmography sensor, and a blood sugar sensor.

Finally, the sensor unit 500 additionally includes a microphone 550 having an internal microphone 551 and an external microphone 552 used for different purposes.

The internal microphone 551 may be used, for example, to analyze the voice of the occupant in the autonomous driving vehicle 1000 based on AI or to immediately respond to a direct voice command of the occupant.

In contrast, the external microphone 552 may be used, for example, to appropriately respond to safe driving by analyzing various sounds generated from the outside of the autonomous driving vehicle 1000 using various analysis tools such as deep learning.

For reference, the symbols illustrated in FIG. 2 may perform the same or similar functions as those illustrated in FIG. 1. FIG. 2 illustrates in more detail a relative positional relationship of each component (based on the interior of the autonomous driving vehicle 1000) as compared with FIG. 1.

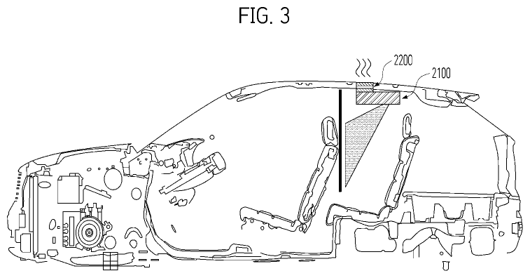

FIGS. 3 to 6 are diagrams for explaining a heat dissipation device for vehicle projectors using a thermal conductor and an external heat sink according to an embodiment of the present disclosure.

As shown in FIG. 3, a projector 2100 is positioned inside a vehicle, and more specifically, the projector 2100 is positioned above the rear seats of the vehicle, allowing the vehicle to be used as a display by outputting images onto the interior structures of the vehicle. The heat dissipation device for vehicle projectors may be configured to dissipate the heat generated by the projector to the outside of the vehicle. The heat dissipation device for vehicle projectors may include a thermal conductor 2200.

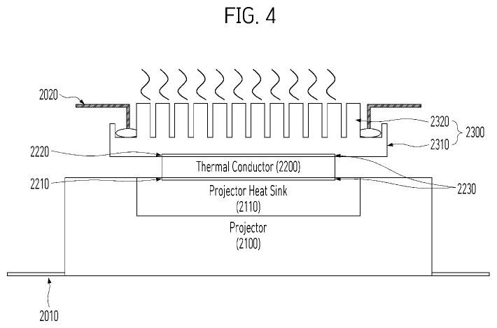

As shown in FIG. 4, the heat dissipation device for vehicle projectors may include: the projector 2100 disposed on a headlining 2010 of a vehicle; a projector heat sink 2110 provided in the projector 2100 and configured to release the heat generated by the projector 2100 to the outside; the thermal conductor 2200 disposed on top of the projector heat sink 2110; and an external heat sink 2300 disposed on top of the thermal conductor 2200 and configured to dissipate the heat released by the thermal conductor 2200 to the outside of the vehicle.

The projector heat sink 2110 may transfer the heat generated by the projector 2100 to the thermal conductor 2200.

The thermal conductor 2200 may facilitate heat exchange between the projector heat sink 2110 and the external heat sink 2300. To this end, the thermal conductor 2200 may include a cold side 2210 that absorbs heat from the projector heat sink 2110 and a hot side 2220 that releases the absorbed heat to the external heat sink 2300.

The heat dissipation device for vehicle projectors may include contact portions 2230 disposed between the thermal conductor 2200 and the projector heat sink 2110 and between the thermal conductor 2200 and the external heat sink 2300. For example, the contact portions 2230 may include thermal pads.

In other words, the contact portions 2230 may include thermal pads disposed between the projector heat sink 2110 and the cold side 2210 of the thermal conductor 2200 and between the hot side 2220 of the thermal conductor 2200 and the external heat sink 2300.

The external heat sink 2300 may include a main body 2310 in contact with the thermal conductor 2200 and protrusions 2320 disposed on the main body 2310. The protrusions 2320 may be formed on the surface of the main body 2310 such that the protrusions 2320 protrude in parallel with each other at equal intervals from the surface of the main body 2310.

The main body 2310 of the external heat sink 2300 may be made of a non-ferrous metal having low thermal resistance, that is, a low heat transfer resistance value and a high heat transfer value. A desirable material is copper, but considering the high cost, aluminum may be used without any issues.

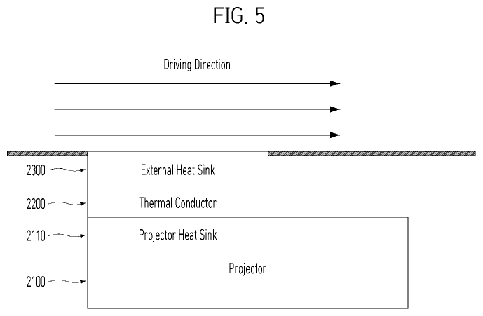

As shown in FIG. 5, the external heat sink 2300 may be exposed to the outside of the vehicle by passing through a roof panel 2020 of the vehicle. The external heat sink 2300 may be arranged in the direction of travel of the vehicle for heat dissipation by the flow of outside air. The external heat sink 2300 may be designed with a structure that maximizes the surface area exposed to the air during driving for efficient heat dissipation.

In this embodiment, the protrusion 2320 has a straight line shape, but the protrusion 2320 may also have a T-shaped configuration. However, the external shapes shown in FIGS. 3 to 6 are merely examples, and thus the scope of the present disclosure is not limited to the illustrated shapes.

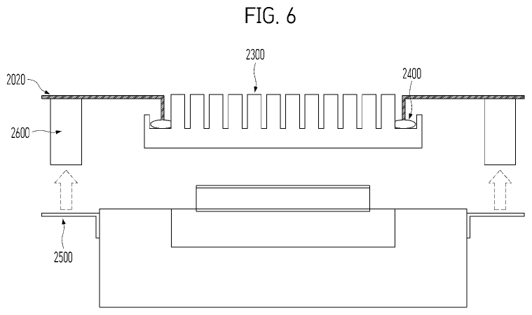

As shown in FIG. 6, the external heat sink 2300 may be coupled to the roof panel 2020 through sealing members 2400. Additionally, first mounting brackets 2500 may be disposed on the sides of the projector 2100, and second mounting brackets 2600 may be disposed underneath the roof panel 2020. The projector 2100 and the external heat sink 2300 may be coupled together through the connection between the first mounting brackets 2500 and the second mounting brackets 2600.

Accordingly, the heat dissipation device for vehicle projectors using the thermal conductor 2200 and the external heat sink 2300 in the vehicle does not create any openings that allow moisture to flow from the outside due to the sealing member 2400 and the coupling between the mounting brackets 2500 and 2600, thereby effectively preventing the ingress of external moisture.

In addition, the heat dissipation device for vehicle projectors using the thermal conductor 2200 and the external heat sink 2300 has an effect of blocking heat transfer into the roof, which is caused by solar radiation.

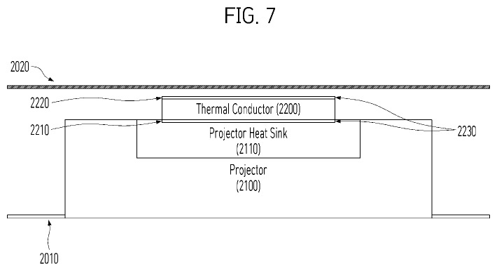

FIGS. 7 to 9 are diagrams for explaining a heat dissipation device for vehicle projectors using a thermal conductor according to an embodiment of the present disclosure.

As shown in FIG. 7, the heat dissipation device for vehicle projectors may include: a projector 2100 disposed on a headlining 2010 of a vehicle, a projector heat sink 2110 provided in the projector 2100 and configured to release the heat generated by the projector 2100 to the outside, and a thermal conductor 2200 disposed on top of the projector heat sink 2110.

The projector heat sink 2110 may transfer the heat generated by the projector 2200 to the thermal conductor 2200.

The thermal conductor 2200 may facilitate heat exchange between the projector heat sink 2110 and a roof panel 2020. To this end, the thermal conductor 2200 may include a cold side 2210 that absorbs heat from the projector heat sink 2110 and a hot side 2220 that releases the absorbed heat to the roof panel 2020.

The heat dissipation device for vehicle projectors may include contact portions 2230 disposed between the thermal conductor 2200 and the projector heat sink 2110 and between the thermal conductor 2200 and the roof panel 2020. For example, the contact portions 2230 may include thermal pads.

In other words, the contact portions 2230 may include thermal pads disposed between the projector heat sink 2110 and the cold side 2210 of the thermal conductor 2200 and between the hot side 2220 of the thermal conductor 2200 and the roof panel 2020.

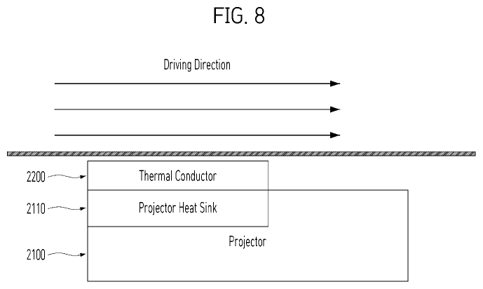

As shown in FIG. 8, the thermal conductor 2200 may make direct contact with the roof panel 2020 of the vehicle to dissipate heat to the outside of the vehicle. Since the roof panel 2020 is made of metal and has a large surface area, the roof panel 2020 may serve as a heat sink. In other words, the roof panel 2020 may dissipate the heat generated by the projector through the flow of outside air, similarly to the heat sink.

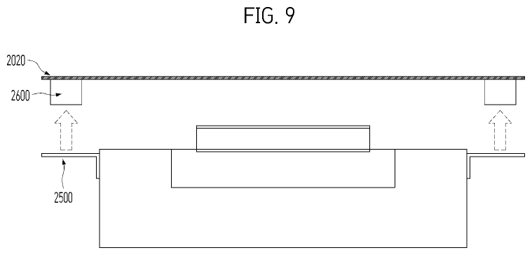

As shown in FIG. 9, first mounting brackets 2500 may be disposed on the sides of the projector 2100, and second mounting brackets 2600 may be disposed underneath the roof panel 2020. The projector 2100 and the external heat sink 2300 may be coupled together through the connection between the first mounting brackets 2500 and the second mounting brackets 2600.

As a result, the thermal conductor 2200 and the roof panel 2020 may be coupled by the mounting brackets, which allows to dissipate the heat generated by the projector without changing the roof design, that is, by maintaining the exterior shape of the vehicle.

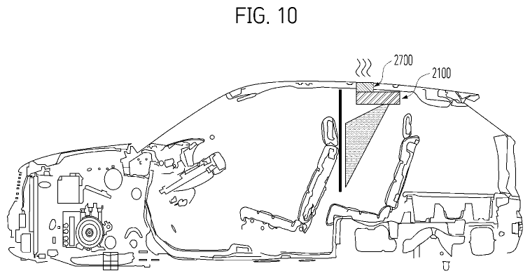

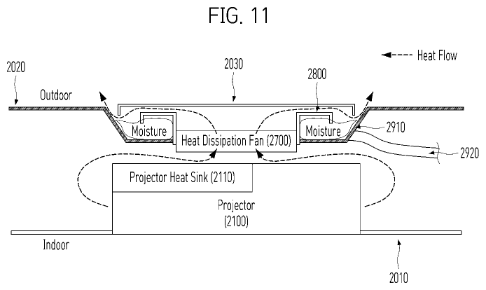

FIGS. 10 and 11 are diagrams for explaining a heat dissipation device for vehicle projectors using a heat dissipation fan according to an embodiment of the present disclosure.

As shown in FIG. 10, a projector 2100 is positioned inside a vehicle, and more specifically, above the rear seats of the vehicle, allowing the vehicle to be used as a display by outputting images onto the interior structures of the vehicle. The heat dissipation device for vehicle projectors may be configured to dissipate the heat generated by the projector to the outside of the vehicle. The heat dissipation device for vehicle projectors may include a heat dissipation fan 2700.

As shown in FIG. 11, the heat dissipation device for vehicle projectors may include: the projector 2100 disposed on a headlining 2010 of the vehicle; and the heat dissipation fan 2700 disposed between the projector 2100 and a roof panel 2020.

The projector 2100 may include a projector heat sink 2110 that transfers the heat generated by the projector 2100 to the outside.

The heat dissipation fan 2700 may be disposed above the projector heat sink 2110. The heat dissipation fan 2700 may release heat in a space between the vehicle headlining 2010 and the roof panel 2020 to the outside.

The roof panel 2020 may have an opening to allow the heat released by the heat dissipation fan 2700 to be discharged to the outside of the vehicle. For example, the upper surface of the roof panel 2020 corresponding to the heat dissipation fan 2700 may be open. The roof panel 2020 may be sloped such that the heat is guided to the outside along the outer surface of the roof panel 2020.

The heat dissipation device for vehicle projectors using the heat dissipation fan 2700 may include a cover panel 2030 coupled to the open upper surface of the roof panel 2020 and configured to prevent the heat dissipation fan 2700 from being exposed to the outside. Consequently, the heat dissipation device for vehicle projectors according to the present disclosure may prevent the ingress of external foreign substances and moisture due to the cover panel 2030.

The heat dissipation device for vehicle projectors using the heat dissipation fan 2700 may include a barrier 2800 formed between the heat dissipation fan 2700 and the roof panel 2020 and configured to prevent moisture that enters through a gap between the roof panel 2020 and the cover panel 2030 from entering the heat dissipation fan 2700. The barrier 2800 may have a folding structure that extends towards the cover panel 2030 to prevent the ingress of moisture.

The heat dissipation device for vehicle projectors may include: a drain hole 2910 formed on the slope of the roof panel 2020 and configured to discharge the incoming moisture; and a drain hose 2920 connected to the drain hole 2910 and configured to discharge the incoming moisture to the outside of the heat dissipation device for vehicle projectors.

Therefore, the heat dissipation device for vehicle projectors according to the present disclosure may prevent the ingress of moisture from the outside through the heat dissipation fan 2700 during rainy conditions.

Various embodiments of the present disclosure do not list all available combinations but are for describing a representative aspect of the present disclosure, and descriptions of various embodiments may be applied independently or may be applied through a combination of two or more.

A number of embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A heat dissipation device, comprising:
a projector disposed on a headlining of a vehicle;
a projector heat sink provided in the projector, the projector heat sink being configured to conduct heat generated by the projector towards an outside of the projector;
a thermal conductor disposed on top of the projector heat sink; and
an external heat sink disposed on top of the thermal conductor, the external heat sink being configured to dissipate heat conducted by the thermal conductor to an outside of the vehicle,
wherein the thermal conductor is configured to facilitate heat exchange between the projector heat sink and the second heat sink by transferring the heat from the projector heat sink to the heat sink.

2. The heat dissipation device of claim 1, wherein the thermal conductor comprises:
a first side configured to absorb heat from the projector heat sink; and
a second side configured to release the absorbed heat to the external heat sink.

3. The heat dissipation device of claim 1, wherein the external heat sink comprises:
a main body in contact with the thermal conductor; and
protrusions disposed on the main body,
wherein the protrusions are exposed to the outside of the vehicle by passing through a roof panel of the vehicle and arranged in a direction of travel of the vehicle for heat dissipation by a flow of outside air.

4. The heat dissipation device of claim 1, further comprising:
a first plurality of thermal pads disposed between the projector heat sink and a first side of the thermal conductor; and
a second plurality of thermal pads disposed between a second side of the thermal conductor and the external heat sink.

5. A heat dissipation device, comprising:
a projector disposed on a headlining of a vehicle;
a projector heat sink provided in the projector, the projector heat sink being configured to release heat generated by the projector to an outside of the projector; and
a heat dissipation fan disposed above the projector heat sink, the heat dissipation fan being configured to release heat from a space between the headlining and a roof panel to an outside of the vehicle.

6. The heat dissipation device of claim 5, wherein the roof panel includes an opening defined therein configured to allow the heat released by the heat dissipation fan to be discharged to the outside of the vehicle, and
wherein the roof panel is sloped to guide the heat to the outside of the vehicle.

7. The heat dissipation device of claim 6, further comprising a cover panel coupled to an open upper surface of the roof panel, the cover panel being configured to prevent the heat dissipation fan from being exposed to the outside of the vehicle.

8. The heat dissipation device of claim 7, further comprising a barrier formed between the heat dissipation fan and the roof panel, the barrier being configured to prevent moisture that enters through a gap between the roof panel and the cover panel from entering the heat dissipation fan.

9. The heat dissipation device of claim 8, wherein the roof panel includes a drain hole defined within a slope of the roof panel, and
wherein the heat dissipation device further comprises a drain hose connected to the drain hole and configured to discharge the entering moisture to an outside of the heat dissipation device.

10. A device, the device comprising:
a first heat sink associated with an electronic device exposed in a passenger area of a vehicle;
a thermal conductor provided on the first heat sink; and
a second heat sink provided on a first side of the thermal conductor, the first heat sink being provided on a second side of the thermal conductor opposite to the first side of the thermal conductor, the second heat sink being configured to dissipate heat from the electronic device to an outside of the vehicle.

11. The device of claim 10, wherein the electronic device is provided in a headlining of a vehicle.

12. The device of claim 10, wherein the electronic device comprises a projector provided in a headlining of a vehicle.

13. The device of claim 10, wherein the thermal conductor is configured to transfer heat from the first heat sink to the second heat sink.

14. The device of claim 10, wherein the second heat sink comprises:
a main body disposed on the second side of the thermal conductor; and
protrusions extending from the main body.

15. The device of claim 14, wherein the vehicle comprises:
a roof having an opening defined therein to receive the protrusions,
wherein the protrusions are configured to extend to an outside from the roof.

16. The device of claim 14, wherein the vehicle comprises:
a roof having an opening defined therein to receive the second heat sink,
wherein the second heat sink in incorporated into the roof, and
wherein the protrusions are configured to extend to an outside from the roof.

17. The device of claim 10, wherein the vehicle comprises:
a roof portion configured to house the electronic device,
wherein the second heat sink contacts a roof panel of the roof portion, the second heat sink being configured to dispel the heat to an outside of the vehicle through the roof portion.
